(19) United States
(12) Patent Application Publication
(10) Pub. No.: US 2026/0101809 A1
(43) Pub. Date: Apr. 9, 2026

(54) ENCAPSULATED HYBRID BONDED STRUCTURES

(71) Applicant: ADEIA SEMICONDUCTOR BONDING TECHNOLOGIES INC., San Jose, CA (US)

(72) Inventors: Patrick VARIOT, Los Gatos, CA (US); Belgacem HABA, Saratoga, CA (US); Hong SHEN, Palo Alto, CA (US); Rajesh KATKAR, Milpitas, CA (US)

(21) Appl. No.: 18/823,472

(22) Filed: Sep. 3, 2024

(51) Int. Cl. H01L 23/00; H01L 23/29; H01L 23/373; H01L 25/065

(52) U.S. Cl. CPC H10W 74/473; H10W 40/25; H10W 72/944; H10W 80/743; H10W 90/00; H10W 90/26; H10W 90/792; H10W 90/794

(57) ABSTRACT

An electronic component including a first device die hybrid bonded to a carrier, an encapsulant encapsulating side surfaces of the first device die and a cover element disposed over directly bonded to a top surface of the first device die. The encapsulant comprises particles embedded therein, and wherein an interface between a top surface of the encapsulant and a bottom surface of the cover element lacks ground particles

### BACKGROUND

### Field

The field relates to integrated circuit packages and/or components having multiple dies, and in particular to encapsulated hybrid bonded structures.

### Description of the Related Art

In one electronic device fabrication process, one or more integrated circuit (IC) dies (“chips”) are attached to a wafer which may then be singulated to make electronic components for connection to an external substrate, such as a system board. In some configurations, the package may include an IC die mounted on another IC die or an interposer. Additionally, both active and passive interposers may include one or more redistribution layers (RDL) for better distribution of power, ground and signals allowing for the addition of extra microbumps for bonding.

The conventional method for fabricating IC packages is laborious and expensive. An example of the conventional method is illustrated in FIGS. 2A-2E. As illustrated in FIG. 2A, a die stack 216 comprising, for example, high bandwidth memory (HBM) dies 204A, 204B, 204C, 204D and a logic die 204E are mounted to a carrier 202. The carrier 202 may be any suitable type of interposer. As illustrated in FIG. 2B, the carrier 202, the die stack 216 and the logic die 204E are encapsulated with an encapsulant 210. In some arrangements, the encapsulant can comprise an inorganic dielectric such as a silicon oxide and/or silicon nitride material. When using an inorganic encapsulant, a thick layer (e.g., a thick silicon oxide layer) is deposited. However, the oxide deposition process is slow and expensive, and it may be challenging or impossible to form suitably thick layers. Alternatively, the encapsulant may be an organic material, such as a epoxy or other organic material, and may include embedded particles 211, such as silica particles.

Next, as illustrated in FIG. 2C, the structure illustrated in FIG. 2B is planarized, such as by chemical-mechanical polishing (CMP) to expose the top surfaces 215 of the die stack 216 and the logic die 204E. If an organic encapsulant with embedded particles 211 was used, the planarizing process produces an encapsulant surface 218 of organic material and partially polished embedded particles 211 as illustrated in FIG. 2D. The partially polished particles 219 are asymmetric due to the polishing. That is, the partially polished particles 219 have different size exposed surfaces. Further, the exposed surfaces of the partially polished particles 219 may have different shapes if the particles are not spherical. In addition, exposed surfaces of the partially polished particles 219 can be planar while the lower embedded portions are rounded. Further, because the organic material and the embedded particles 211 etch at different rates, voids 217 in the organic material at the surface 218 may form, especially if some of the embedded particles 211 pop out of the organic material during planarizing. Note, when using an adhesion layer 212, as discussed below, the presence of voids 217 and partially polished embedded particles 211 does not affect the bonding of the cover wafer 206 to the exposed surfaces of the die stack 216 and the logic die 204E.

As illustrated in FIG. 2E, an adhesive layer 212 is deposited over the planarized structure illustrated in FIG. 2C. Finally, a cover wafer 206 is attached to the structure illustrated in FIG. 2C via the adhesive layer 212. The cover wafer 206 may be a structural support element and/or a heat dissipation wafer. In some embodiments, the carrier 202 may have through substrate vias (e.g. through silicon vias (TSVs) in silicon interposers), which can be revealed and bumped as part of interposer thinning process (after application of the encapsulant 210 or cover wafer 206 is attached and acts as a support for interposer thinning and TSV reveal process).

It would be desirable to provide methods and structures for fabricating electronic components which are less expensive, yet provide superior bonding of the cover wafer than conventional methods.

### BRIEF DESCRIPTION OF THE DRAWINGS

Specific implementations will now be described with reference to the following drawings, which are provided by way of example, and not limitation.

FIGS. 1A-1B schematically illustrate a process for forming a directly hybrid bonded structure without an intervening adhesive according to some embodiments.

FIGS. 2A-2E are cross-sectional diagrams illustrating a conventional method of making hybrid electronic components.

FIGS. 3A-3C are cross-sectional diagrams illustrating a method of making hybrid bonded electronic components according to some embodiments of the disclosed technology.

FIGS. 4A-4C are cross-sectional diagrams illustrating another method of making hybrid electronic components according to other embodiments of the disclosed technology.

FIGS. 5A-5C are cross-sectional diagrams illustrating another method of making hybrid electronic components according to other embodiments of the disclosed technology.

FIGS. 6A-6C are cross-sectional diagrams illustrating another method of making hybrid electronic components according to other embodiments of the disclosed technology.

FIGS. 7A-7D are cross-sectional diagrams illustrating another method of making hybrid electronic components according to other embodiments of the disclosed technology.

FIG. 8 is a process flow diagram illustrating a method of making example hybrid electronic components according to some embodiments of the disclosed technology.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The following description refers to integrated circuit packages. Specifically, the following description refers to integrated circuit packages having hybrid bonded integrated circuits.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Ser. No. 63/524,564 , filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

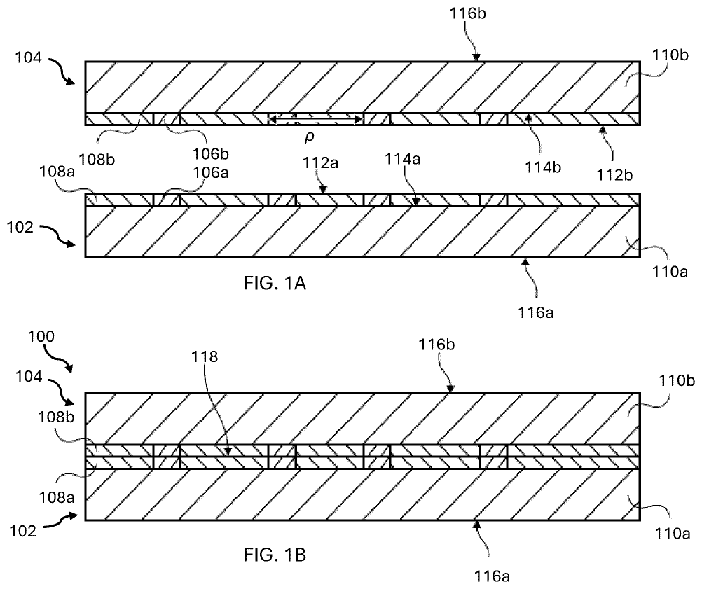

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry, not shown, can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106 and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

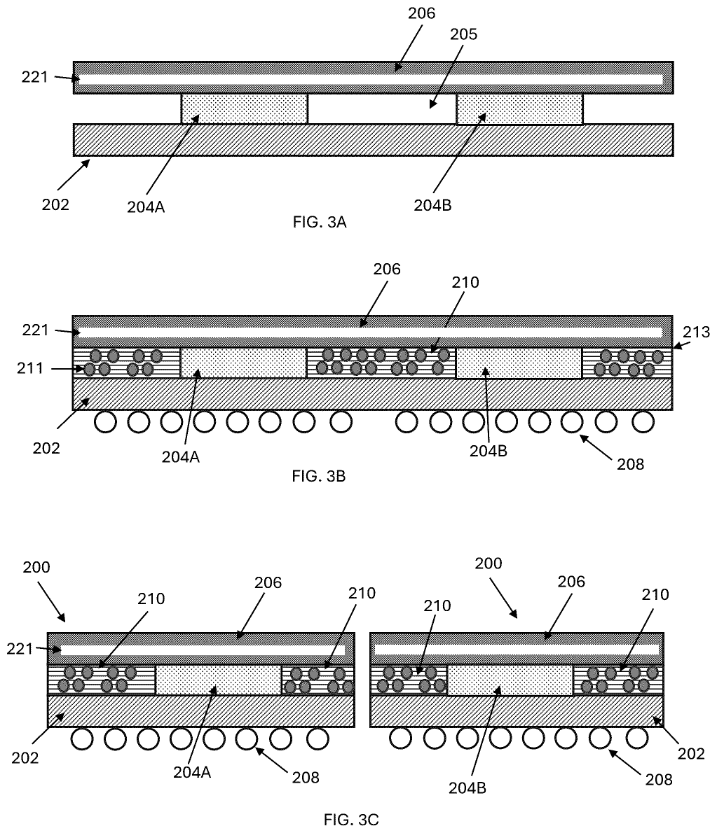

FIGS. 3A-3C are cross-sectional diagrams illustrating a method of making hybrid bonded electronic components according to some embodiments of the disclosed technology. As illustrated in FIG. 3A, first die 204A and a second die 204B may be attached to a carrier 202. In an embodiment, the first die 204A and the second die 204B are attached to the carrier 202 by hybrid bonding. In embodiments, the first and second dies 204A, 204B may have contact pads on their bottom surfaces as explained above in connection with FIGS. 1A-1B. Further, the carrier 202 may also have contact pads on the top surface. In embodiments, the contact pads on the first and second dies 204A, 204B may be aligned with (and directly bonded to) the contact pads on the carrier 202. The carrier 202 may be an interposer which may optionally include one or more RDLs. An interposer may be a substrate, for example, an IC die, a semiconductor (e.g., silicon), dielectric (e.g., glass), or ceramic substrate with embedded conductive traces and vias. Depending on the application, the carrier 202 may comprise PCB or organic substrates. For direct bonding applications an inorganic bonding layer, e.g., silicon oxide, would be added over the organic layer(s). In some embodiments, carrier 202 may be an interposer. In some embodiments, an interposer may be a passive die (e.g. glass or silicon die without any active devices) or may have passive elements (e.g., capacitors, resistors) located therein or thereon. Further, the interposer may include active circuitry. In other embodiments, the carrier 202 may comprise a reconstituted structure (e.g., one or more dies (e.g. active and/or passive dies) encapsulated in a dielectric (inorganic or organic) encapsulant. Next, a cover element 206 may be attached to the top surfaces of the first die 204A and the second die 204B. The cover element 206 may be attached by direct bonding without an adhesive. In other embodiments, the cover element 206 can be attached to the dies 204A, 204B with an adhesive. In various embodiments,, a planarization step (e.g., a CMP process) may be performed on the first and second dies 204A, 204B prior to attaching the cover element 206. In various embodiments, the dies 204A, 204B may come from different wafers which may have different thicknesses. Planarizing the dies may thin the dies to approximately the same thickness so as to create a planar surface suitable for direct bonding. A difference in die thickness may adversely affect or render impossible direct bonding of the cover element 206 (discussed in more detail below) to the top surfaces of the dies 204A, 204B. Polishing the dies 204A, 204B makes the dies 204A, 204B level and ready for direct bonding.

The cover element 206 may be made of a thermally conductive material provided to convey heat away from the first and second dies 204A, 204B. That is, the cover element 206 made be made of a material having a higher conductivity than the encapsulant 210. Example materials include, but are not limited to silicon, copper, diamond blocks (e.g., single crystal diamond) or the like, nano-fiber blocks, nano-porous metal (e.g., W) filled blocks, graphite, or GeSe Further the cover element 206 cooling element that includes one or more channels 221 or cavities within which or through which a liquid can be disposed. In addition, the cover element 206 may provide structural support for the bonded structure, for example, the support the components during operation or due to thermally-induced stresses. As illustrated in FIG. 3A, with the bonding of cover element 206 to the first and second dies 204A, 204B, cavities 205 are formed between the first and second dies 204A, 204B other dies, not shown. Although only two dies are illustrated in FIG. 3A, any number of dies may be bonded to the first wafer, such as 1-1000 dies, such as 5-500 dies, such as, 10-1000 dies.

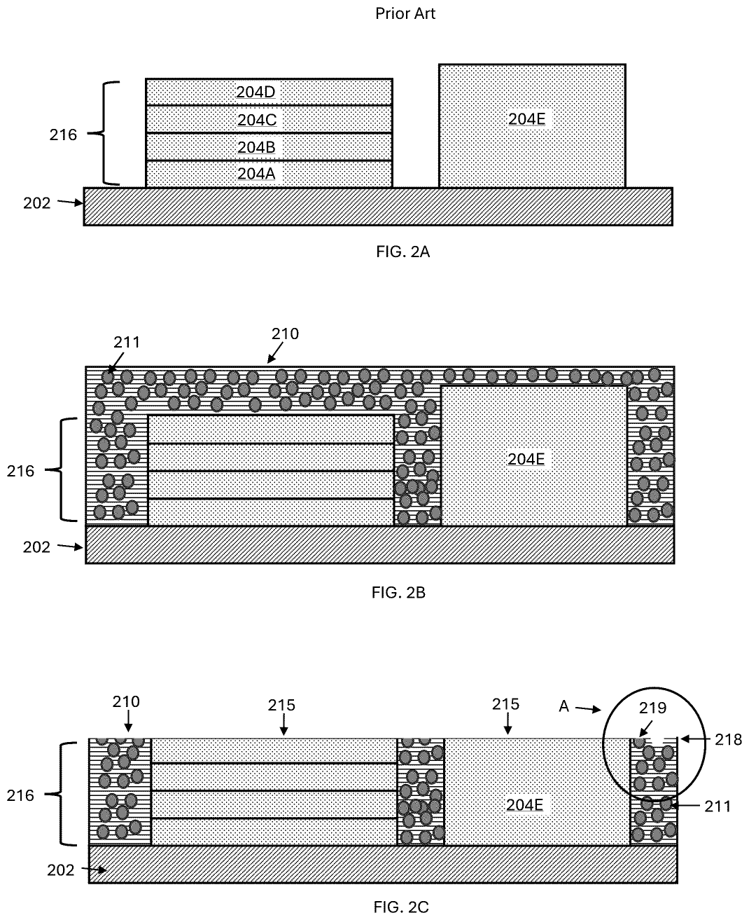

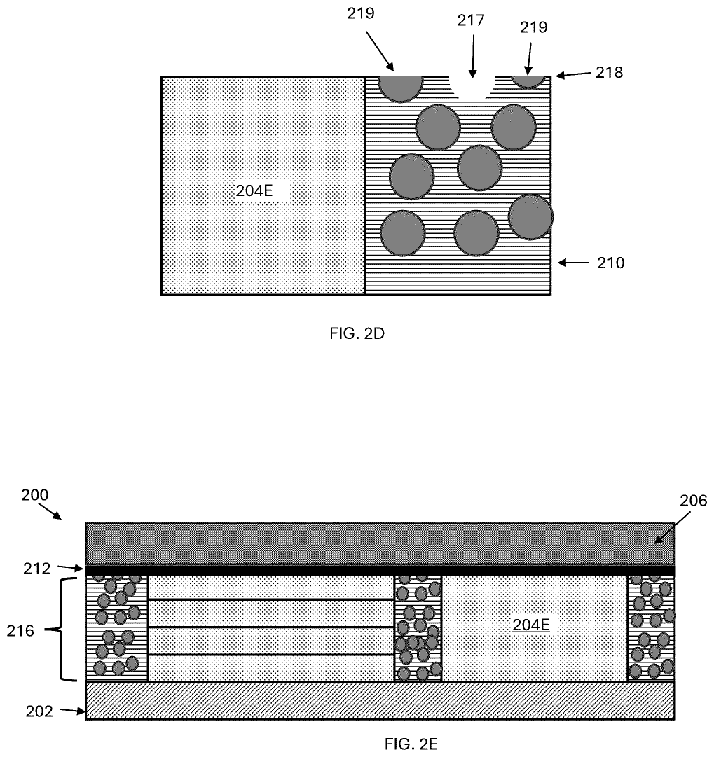

As illustrated in FIG. 3B, an encapsulant 210 may be flowed or deposited in the cavities 205 between adjacent device dies 204A, 204B. In some embodiments, the dielectric or encapsulant 210 may be an organic material (e.g. polymer, thermosetting materials, epoxy molding compound, underfill compound resins, etc.). In some embodiments, the encapsulant 210 can be provided using a transfer or compression molding process. In some embodiments, the encapsulant is provided as a liquid which fills the cavities 205 and then hardened by exposure to ultraviolet light or hardened by heating. In some embodiments, the encapsulant 210 may include embedded particles 211 which have a relatively high thermal conductivity relative to the organic matrix to increase thermal conductivity of the encapsulant 210. Particle materials include, but are not limited to, silica fillers carbides, graphene and alumina. In various embodiments, the particles can comprise stress relief particles, such as silicone particles. Advantageously, the organic encapsulant 210 may provide less stress than an inorganic dielectric encapsulant. For example, the encapsulant 210 may include particles 211 made of silicone. Further, by providing the encapsulant 210 after bonding the cover element 206 to the first and second dies 204A, 204B, the encapsulant can be provided at a temperature lower than the bonding (and subsequent annealing) temperature. This results in the generation of lower thermal stresses. Further, as planarization of the first and second dies 204A, 204B can be performed prior to bonding the cover element 206, and therefore, prior to providing the encapsulant 210, the encapsulant need not be planarized. Therefore, there are no concerns with partially etched or ground particles 211 or unwanted contamination at the interface 213 between the first and second dies 204A, 204B and the cover element 206. That is, when the cover element 206 is attached, the interface 213 between the top surface of the encapsulant 210 and the bottom surface cover element 206 lacks partially polished or ground particles 219 or unwanted contamination. Moreover, an interface between a top surface of the encapsulant 210 and a bottom surface of the cover element 206 can comprise an adhesive bond (not a direct bond, e.g., not a uniform direct bond, but rather a bottom surface of the cover element 206 is adhered to the encapsulant 210) between the organic encapsulant 210 and the cover element 206. In embodiments, the cover element 206 is directly bonded to the first device die 204A and adhesively bonded to the organic encapsulant 210 (e.g., there is no direct bond between the organic encapsulant and the cover element 206). Beneficially, unlike the structure in FIGS. 2A-2E, in the embodiment of FIGS. 3A-3C, the direct bonding of the cover element 206 to the dies 204A, 204B can be conducted in a cleanroom or fabrication line process before providing the organic encapsulant 210. As explained above, in the process flow of FIGS. 2A-2E, direct bonding can be challenging or unfeasible due to the presence of the organic encapsulant (and its attendant contamination) before the bonding process. Directly bonding the cover element 206 to the dies 204A, 204B before encapsulating with the organic material prevents any negative effects that contaminants from the molding process would have on the direct bond. Thus, in the structure of FIG. 3B, the upper surface of the encapsulant 210 is not a polished surface. Rather, there is an adhesive bond between the organic encapsulant 210 and the carrier 206.

As illustrated in FIG. 3C, the structure of FIG. 3B may be singulated to form individualelectronic components 200. In some embodiments (e.g. when carrier 202 is silicon interposer), carrier 202 is thinned and TSVs in carrier 202 are revealed and contacts are formed at the bottom, prior to singulation. In some other embodiments (e.g. carrier 202 is reconstituted wafer), through dielectric vias (not shown) are formed in the reconstituted portion of the carrier and/or the TSVs in the dies (e.g. bridge dies, not shown) embedded in the reconstituted wafer 202 are exposed. In some embodiments, RDL is formed at the bottom of the reconstituted wafer 202. The individual electronic components 200 may then be attached to a substrate, not shown, to form an electronic device. Attachment of the electronic components 200 to the substrate may be accomplished, for example, by providing solder balls 208, or any other suitable equivalent, to the carrier 202 electronic components 200 and then bonding the electronic components 200 to bonding pads on the wafer by heating to melt the solder balls 208. In other embodiments, the electronic component 200 may be direct bonded to another substrate or carrier. Advantages of the present embodiment and the embodiments below include a cleaner attachment, such as by direct (e.g., hybrid or uniform) bonding, of the cover element 206 to the first and second dies 204A, 204B while simplifying the attachment process. Further, encapsulating after performing the attachment steps allows all bonding steps to be performed in a clean environment. That is, direct bonding of the cover element 206 may be accomplished prior to the introduction or deposition of the organic encapsulant 210. Further, the methods of the embodiments described herein are not limited by die thickness, allowing for the fabrication of device packages 200 including stacks of dies as discussed in more detail below. In addition, embodiment methods allow the attachment of active or passive heat dissipation devices. Embodiment methods also allow for the use of a wide range of encapsulant materials include encapsulant with higher thermal conductivity, low stress encapsulants and organic encapsulants. Further, embodiment methods allow the use of lower cost encapsulants and lower cost methods as existing wafer molding equipment may be used to provide the encapsulant.

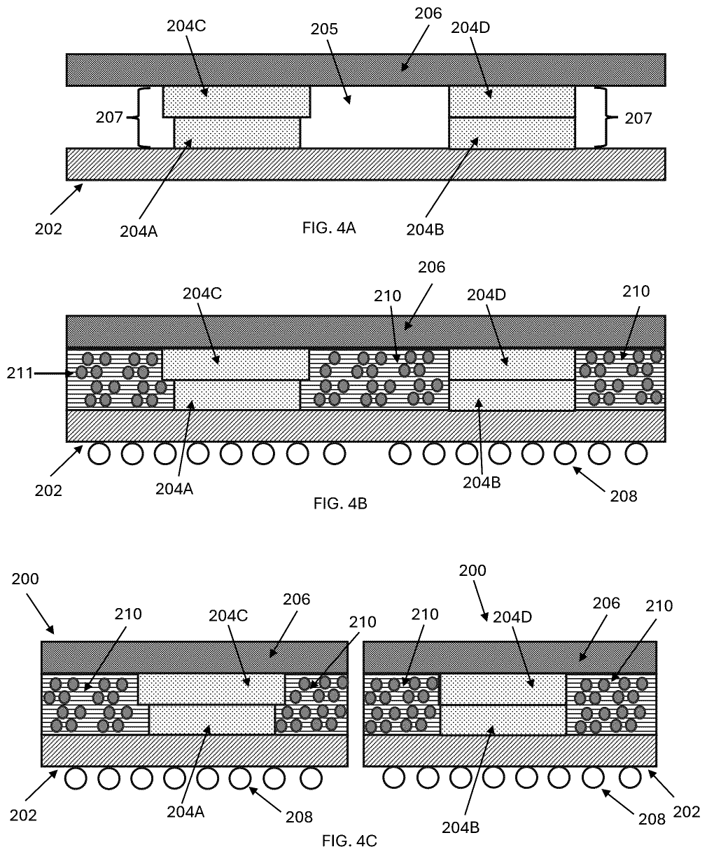

FIGS. 4A-4C are cross-sectional diagrams illustrating another method of making hybrid bonded electronic components according to some embodiments of the disclosed technology. As illustrated in FIG. 3A, first die 204A and a second die 204B may be attached to a carrier 202. In an embodiment, the first die 204A and the second die 204B are attached to the carrier 202 by direct bonding (e.g., hybrid bonding). Then, third and fourth device dies 204C, 204D are attached to the first and second device dies 204A, 204B, respectively, to form die stacks 207. In some embodiments, the third and fourth device dies 204C, 204D may be attached to the first and second device dies 204A, 204B by direct (e.g., hybrid) bonding. In embodiments, contact pads may be formed on the top surfaces of the first and second device dies 204A, 204B and the bottom surfaces of the third and fourth device dies 204C, 204D to facilitate hybrid bonding. Further, first and second dies 204A, 204B, may include TSVs to provide electrical connection between the carrier 202 and the third and fourth device dies 204C, 204D. Next, a cover element 206 is attached to the top surfaces of the third and fourth device dies 204C, 204D. In some embodiments, one of the die stacks 207, or any of the dies 204A-204D, may comprises dummy dies rather than active device dies with active circuitry (e.g., transistor(s)). Dummy dies may comprise a block of semiconductor material (e.g. silicon) or other material with a thermal conductivity greater than the encapsulant 210. Dummy dies may enhance the dissipation of heat away from hotter (e.g. active dies). In some embodiments, at least one of the upper dies in a die stack 207, see FIGS. 4A-4C, may be dummy dies. In some embodiments, at least one of the dies (e.g., die 204C) may have a larger lateral footprint than the other die (e.g., die 204A). Dummy dies may be completely devoid of active circuitry or they may have a relatively small number of active devices, e.g. 5% or fewer transistors, relative to the active dies. Further dummy dies may include vias, such as through silicon vias (TSV), such as copper TSVs to further improve heat dissipation. In some embodiments, the dummy dies may comprise passive electronic elements and/or pass through vias. In some embodiments where upper die is not a dummy die and the upper die is bonded to the bottom die via hybrid bonding, and the bottom die can have TSVs to form electrical connections between the upper die and the carrier (e.g. interposer).

As illustrated in FIG. 4B, an encapsulant 210 may be flowed or deposited in the cavities 205 between adjacent die stacks 207. As in the previous embodiment, the top surfaces of the third and fourth dies 204C, 204D may be planarized so that the die stacks 207 are the same height. As in the previous embodiment, the encapsulant 210 may include particles 211, for example, conductive particles. Further, as in the previous embodiment, providing the encapsulant 210 after attaching the cover element 206 to the tops of the third and fourth device dies 204C, 204D, 210 after attaching the cover element 206 to the tops of the third and fourth device dies 204C, 204D, allows the use of an organic encapsulant and avoids the problems, such as voids and partially etched particles (which may adversely affect direct/hybrid bonding) at the interface between the encapsulant 210 and the cover element 206, associated with bonding the cover element 206 after providing the encapsulant 210. In various embodiments, the dies 204A, 204B, 204C, 204D may come from different wafers which may have different thicknesses resulting in die stacks 207 with different thicknesses. As discussed above, planarizing the dies may thin the dies to approximately the same thickness (stack thickness) so as to create a planar surface suitable for direct bonding. Polishing the dies 204C, 204D makes the die stacks 2007 level and ready for direct bonding. As illustrated in FIG. 4C, the intermediate structure illustrated in FIG. 4B can be singulated to form individual electronic components 200. This embodiment includes all of the advantages of the previous embodiment. However, it further includes the advantage of being to use an encapsulant that can encapsulate a die stack 207. Further, as illustrated in FIGS. 4A-4C, the die stacks 207 only include two dies. However, any number of dies may be stacked to form the die stack 207. For example, the device illustrated in FIGS. 2A-2E having a die stack 207 of four HBM dies 204A-204D and a microprocessor die 204E may be fabricated by methods disclosed herein. As explained above, and unlike the process of FIGS. 2A-2E, directly bonding the cover element 206 to the dies 204C, 204D before encapsulating with the encapsulant 210 can beneficially prevent any contaminants from the organic encapsulant from reducing the bond strength between the cover element 206 and the dies 204C, 204D.

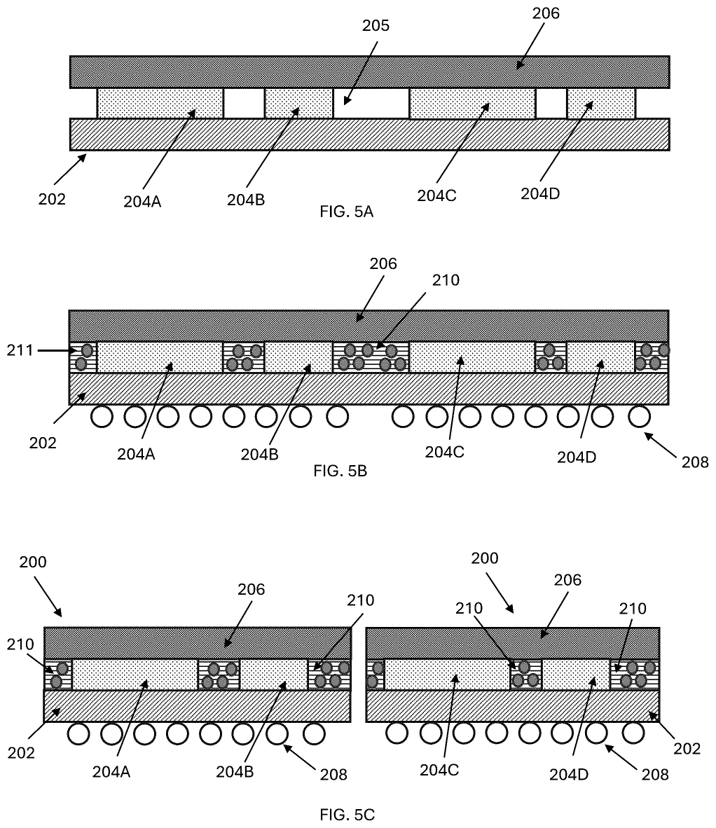

FIGS. 5A-5C are cross-sectional diagrams illustrating another method of making hybrid bonded electronic components 200 a according to some embodiments of the disclosed technology. As illustrated in FIG. 5A, first, second, third and fourth device dies 204A, 204B, 204C, 204D are attached to a carrier 202. Next, a cover element 206 is attached to top surfaces of the first, second, third and fourth device dies 204A, 204B, 204C, 204D. In some embodiments, the cover element 206 is direct of hybrid bonded to the top surfaces of the first, second, third and fourth device dies 204A, 204B, 204C, 204D. Unlike the previous embodiments which only disclosed a single die 20A or 204B or die stack 207 in a device package 200, the present embodiment illustrates that a device package 200 may include multiple adjacent dies/die stacks. Further, the adjacent dies/die stacks may include dies 204A, 204B having different widths. In addition to multiple chips in the CoW package 200, the functionality of the chips may also be different. For example, if first die 204A is a processor (e.g. GPU, CPU, NPU, TPU, etc.), second die 204B can be memory. Alternatively, one die may be a CPU, while the other may be a GPU. Further, one of first die 204A or second die 204B may be a die stack 207 of any suitable number of dies, e.g. 204A may be a GPU while die 204B may be a HBM stack. The initial thicknesses of the first and second dies 204A, 204B (or die stack 207 as the case may be) may be different, and therefore a polishing step may be used.

As illustrated in FIG. 5B, an encapsulant 210 is provided in the cavities 205 between adjacent device dies 204A, 204B, 204C, 204D. As in the previous embodiments, the encapsulant 210 may include particles 211, such as thermally conductive particles. As illustrated in FIG. 4C, the intermediate structure illustrated in FIG. 5B may be singulated to form individual electronic components 200. When singulated, each of the electronic components 200 includes two device dies. In alternative embodiments, each of the electronic components 200 may include more than two device dies, such as 3, 4, 6, 10 or any other number of device dies. In some embodiment, one or more of the dies bonded to carrier 202 can be a die stack (e.g. memory stack or HBM). Further, the current embodiment and the previous embodiment can be combined. That is, the electronic components 200 may include multiple die stacks 207.

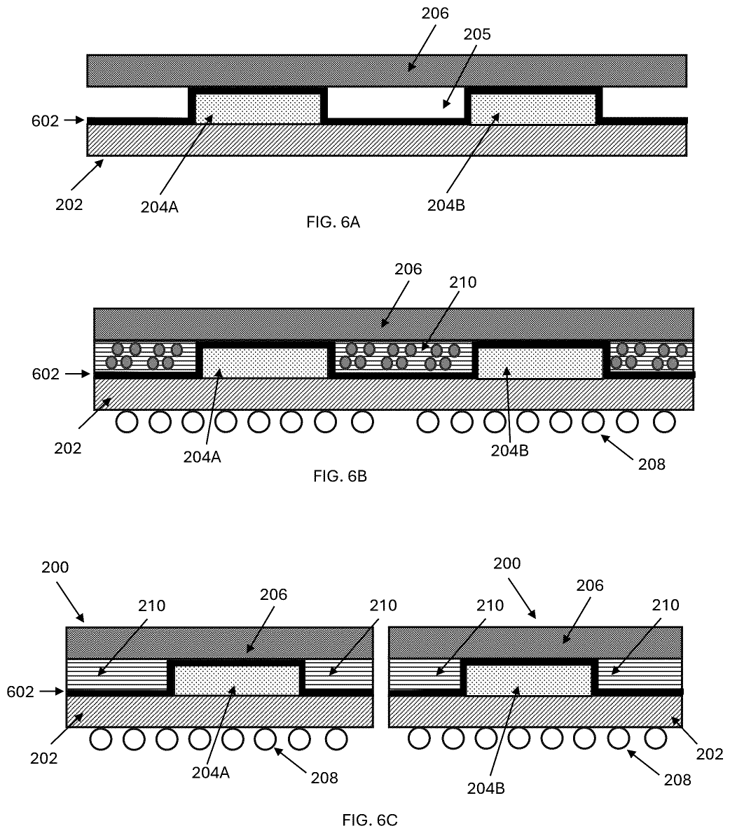

FIGS. 6A-6C are cross-sectional diagrams illustrating another method of making hybrid bonded Electronic components 200 according to some embodiments of the disclosed technology. As illustrated in FIG. 6A, a first die 204A and a second die 204B may be attached to a carrier 202. In an embodiment, the first die 204A and the second die 204B are attached to the carrier 202 by direct (e.g., hybrid) bonding. As in any of the embodiments discussed herein, the top surfaces of the first and second device dies 204A, 204B may then be planarized. Next, a conformal layer 602 may be deposited over the exposed top surface of the carrier 202 and the side and top surfaces of the first and second dies 204A, 204B. The conformal layer 602 may be made of any suitable material, such as a silicon based dielectric layer, e.g., silicon oxide or silicon nitride. The conformal layer 602 may be a protective layer and/or bonding layer which protects the dies from moisture and may aid in bonding the cover element 206 to the first and second device dies 204A, 204B. The protective layer may also mitigate stress. In some embodiments, the conformal layer can comprise one or more layers and may assist in improving adhesion between the die stack 207 and the downstream process of encapsulation deposition illustrated in FIG. 6B. In some embodiments the conformal layers may also advantageously conduct heat. Alternatively, the conformal layer 602 may be an oxide, nitride, oxynitride or carbonitride. A cover element 206 may then be attached to the top surfaces of the first die 204A and the second die 204B with the conformal layer 602.

As illustrated in FIG. 6B, an encapsulant 210 is provided in the cavity 205 between adjacent device dies 204A, 204B. As in the previous embodiments, the encapsulant 210 may include particles 211, such as thermally conductive particles. Particle materials include, but are not limited to, silica fillers, carbides, graphene and alumina. As illustrated in FIG. 6C, the intermediate structure illustrated in FIG. 6B may be singulated to form individual electronic components 200.

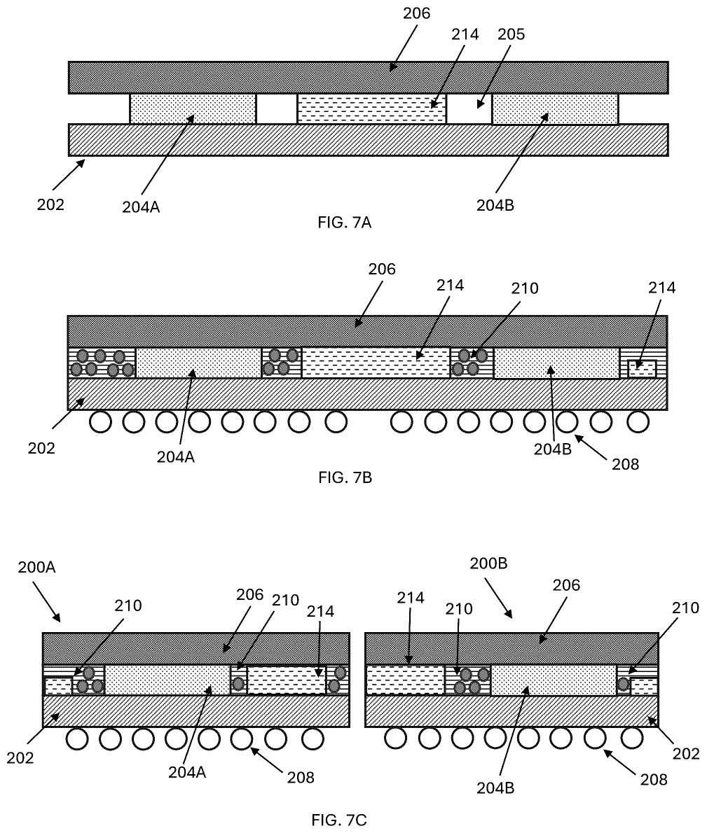

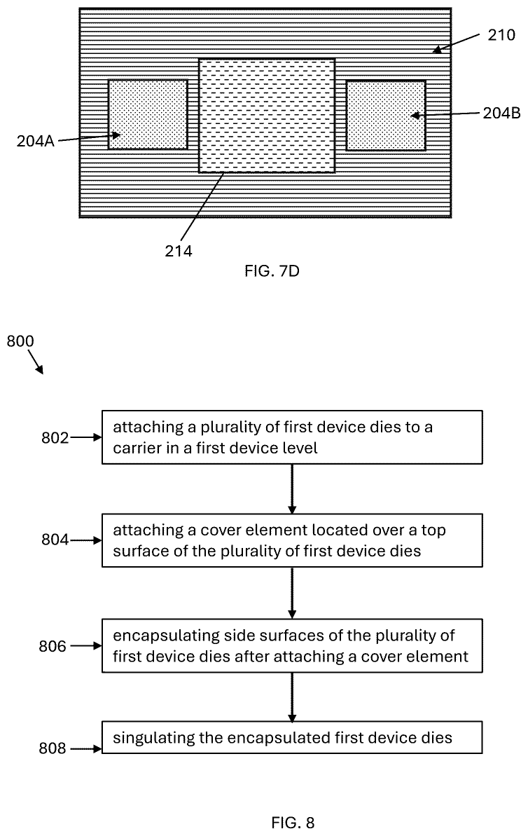

FIGS. 7A-7C are cross-sectional diagrams illustrating another method of making hybrid bonded Electronic components according to some embodiments of the disclosed technology. As illustrated in FIG. 7A, a first device die 204A and a second device die 204B may be attached to a carrier 202. In an embodiment, the first device die 204A and the second device die 204B are attached to the carrier 202 by direct (e.g., hybrid) bonding. In this embodiment, an element 214 may be attached to the carrier 202 between the first and second device dies 204A, 204B. The element 214 may be a heat dissipation element, a dummy element, a structural element to provide structural integrity to the component, etc. The element 214 may be attached by any suitable method, such as by direct bonding (e.g., uniform bonding or hybrid bonding). The element 214 may be made of any suitable heat conductive material. As discussed above the heat dissipation element may be made of materials such as silicon, copper, diamond blocks (e.g., single crystal diamond) or alike, nano-fiber blocks, nano-porous metal (e.g., W) filled blocks, graphite, or GeSe. In some embodiments, the element 214 may be an element without any functionalities (e.g. passive silicon). In some embodiments, the element 214 can be used for integrity of the process and final package structure (e.g. to balance thermomechanical stresses, reduce warpage, etc.). Further, the heat dissipation element may include cooling channels as discussed above that allows for fluid, gas or liquid, cooling. A cover element 206 may be attached to the top surfaces of the first and second device dies 204A, 204B and the element 214.

As illustrated in FIG. 7B, the element 214 may extend the full distance (e.g., thickness) between the carrier 202 and the cover element 206. Alternatively, the heat dissipation element may only extend a portion of the distance between the carrier 202 and the cover element 206. Further, in some embodiments, the element 214 only partially fills the cavities 205 between adjacent device dies. In these embodiments, the remaining portion of the cavities 205 may be filled with an encapsulant 210.

As illustrated FIG. 7C, the intermediate structure in FIG. 7B may be singulated to form individual electronic components 200A, 200B. In some embodiments, the singulation may result in a side surface of the dissipation element being exposed, e.g. device packages 200B in which singulation is performed through the dissipation element 214. In other embodiments, the intermediate structure in FIG. 7B may be singulated such that the dissipation unit does not have exposed side surfaces, e.g. device packages 200A in which simulation is performed through the encapsulant 210 (and such that the encapsulant 210 is exposed at the side surface). Although the heat dissipation element may extend from the first device die 204A to the second device die 204B, it is advantageous to have encapsulation between the element 214 and the device dies 204A, 204B to reduce stress and prevent crack propagation should either the element 214 or the device dies 204A, 204B have a crack.

FIG. 7D is a plan view of an electronic component 200 with the cover removed. In an embodiment as illustrated in FIG. 7D, the element 214A may have a different footprint than the first and second dies 204A, 204B. As illustrated, the element 214A may have a larger length and width than the first and second dies 204A, 204B. In embodiments, either or both the length and width may be larger or smaller than the first and second dies 204A, 204B.

FIG. 8 is a process flow diagram illustrating a method 800 of making example hybrid Electronic components 200 according to embodiments of the disclosed technology. A first step 802 includes attaching a plurality of first device dies 204A, 204B to a carrier 202 in a first device level. The next step 804 includes attaching a cover element 206 located over top surfaces of the plurality of first device dies 204A, 204B. The next step 806 includes encapsulating side surfaces of the plurality of first device dies 204A, 204B after attaching a cover element 206. Subsequently, a step 808 of singulating the encapsulated first device dies to form chip-on-wafer (CoW) packages 200 is performed. A planarization step may be performed prior to attaching a cover element 206.

In the various methods described herein, encapsulation is performed after direct bonding. Advantageously, all hybrid or direct bonding may be performed in clean environment. In this manner, hybrid or direct bonding may be performed without the presence of organic encapsulation. Further, there is no theoretical limit to the thickness or number of the hybrid bonded dies. This allows for hybrid bonded die stacks. Further, the methods allow for hybrid or direct bonding of active or passive heat dissipation devices. Rather than relying on a limited number of encapsulant materials, a wide range of encapsulant materials may be used, including encapsulant materials with high thermal conductivity, low-stress, especially organic encapsulants. Costs may be lowered by using lower cost encapsulants and encapsulant materials. Further, the encapsulation process may be performed with existing wafer molding equipment.

### EXAMPLES

Example 1. An electronic component comprising:
a first device die bonded (e.g., directly bonded) to a carrier;
a cover element directly bonded to a top surface of the first device die; and
an organic encapsulant encapsulating side surfaces of the first device die, the organic encapsulant extending between the carrier and the cover element,
wherein an interface between a top surface of the encapsulant and a bottom surface of the cover element comprises a cured adhesive bond between the organic encapsulant and the cover element (e.g., the cover element is adhered to the encapsulant).

Example 2. The electronic component of Example 1, wherein the cover element comprises a heat dissipation element.

Example 3. The electronic component of Example 1, wherein the organic encapsulant comprises thermally conducting particles.

Example 4. The electronic component of Example 1, wherein the carrier is an interposer.

Example 5. The electronic component of Example 5, wherein the interposer comprises at least one redistribution layer.

Example 6. An electronic component comprising:
a first device die bonded to a carrier;
an encapsulant encapsulating side surfaces of the first device die; and
a cover element directly bonded to over a top surface of the first device die
wherein the encapsulant comprises particles embedded therein, and wherein an interface between a top surface of the encapsulant and a bottom surface of the cover element lacks ground particles.

Example 7. The electronic component of Example 6, wherein the interface between a top surface of the encapsulant and a bottom surface of the cover element lacks ground particles.

Example 8. The electronic component of Example 6, wherein the particles comprise stress relief particles.

Example 9. The electronic component of Example 6, wherein the particles comprise thermally conducting particles.

Example 10. The electronic component of Example 6, wherein the particles comprise carbides, graphene, or alumina.

Example 11. The electronic component of Example 6, wherein the cover element comprises a heat dissipation wafer.

Example 12. The electronic component of Example 6, wherein the carrier is an interposer.

Example 13. The electronic component of Example 12, wherein the interposer comprises at least one redistribution layer.

Example 14. The electronic component of Example 6, further comprising a second device die stacked in a second device level above the first device die, the second device die hybrid bonded to the first device die.

Example 15. The electronic component of Claim 6, wherein the first die comprises a memory die or a processor die.

Example 16. The electronic component of Example 14, wherein the encapsulant encapsulates side surfaces of the first device die and the second device die.

Example 17. The electronic component of Example 14, wherein the second device is attached to the first device die by hybrid bonding.

Example 18. The electronic component of Example 6, further comprising a second device die hybrid bonded to the carrier adjacent to the first device die in the first device level.

Example 19. The electronic component of Example 13, further comprising a gap between the first and second device dies and the encapsulant encapsulates side surfaces of the first and second device dies.

Example 20. The electronic component of Example 6, further comprising a conformal protective layer located over the carrier, the sides of the first die and the top surface first device die.

Example 21. The electronic component of Example 20, wherein the conformal protective layer comprises an inorganic dielectric material.

Example 22. The electronic component of Example 14, comprising a conformal protective layer located over the carrier, the sides of the first and second device dies and a top surface of the second device die.

Example 23. The electronic component of Example 18, comprising a conformal protective layer located over the carrier, the sides of the first and second device dies and a top surface of the second device die.

Example 24. The electronic component of Example 6, further comprising at least one heat dissipation element attached to the carrier.

Example 25. The electronic component of Example 14, further comprising at least one heat dissipation element attached to the carrier.

Example 26. The electronic component of Example 18, further comprising at least one heat dissipation element attached to the carrier.

Example 27. A method of making an electronic component comprising:
bonding a plurality of first device dies to a carrier in a first device level;
directly bonding a cover element to a top surface of the plurality of first device dies;
encapsulating side surfaces of the plurality of first device dies after attaching the cover element; and
singulating the carrier, cover element and the encapsulated first device dies to form a plurality of electronic components.

Example 28. The method of Example 27, wherein the plurality of first dies are attached by hybrid bonding.

Example 29. The method of Example 27, wherein encapsulating comprises flowing an encapsulant around the plurality of first device dies.

Example 30. The method of Example 27, further comprising curing the encapsulant.

Example 31. The method of Example 27, further comprising attaching one or more electronic components to a substrate.

Example 32. The method of Example 27, further comprising attaching a plurality of second device dies to the plurality first device dies prior to encapsulating the first device die.

Example 33. The method of Example 32, wherein the side surfaces of the first device dies and the second device dies are encapsulated at the same time.

Example 34. The method of Example 27, wherein each electronic component comprises more than one first device die.

Example 35. The method of Example 27, further comprising forming a conformal protective layer over the carrier and the plurality of first device dies before encapsulating.

Example 36. The method of Example 35, further comprising forming a conformal protective layer over the carrier and the plurality of second device dies before encapsulating.

Example 37. The method of Example 27, further comprising attaching a heat dissipation element between adjacent first device dies prior to encapsulation.

Example 38. The method of Example 37, wherein the encapsulant comprises an organic matrix with particles embedded therein and wherein an interface between a top surface of the encapsulant and a bottom surface of the cover element lacks ground particles.

Example 39. An electronic component comprising:
a first device die bonded to a carrier;
an encapsulant encapsulating side surfaces of the first device die; and
a cover element directly bonded to a top surface of the first device die,
wherein a top surface of the encapsulant adjacent a bottom surface of the cover element is an unpolished surface.

Example 40. The electronic component of Example 39, wherein an interface between the top surface of the encapsulant and the bottom surface of the cover element comprises an adhesive bond between the organic encapsulant and the cover element.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. An electronic component comprising:
a first device die bonded to a carrier;
a cover element directly bonded to a top surface of the first device die; and
an organic encapsulant encapsulating side surfaces of the first device die, the organic encapsulant extending between the carrier and the cover element,
wherein a bottom surface of the cover element is adhered to the organic encapsulant.

2. The electronic component of claim 1, wherein the cover element comprises a heat dissipation wafer.

3. The electronic component of claim 1, wherein the organic encapsulant comprises thermally conducting particles.

4. The electronic component of claim 1, wherein the carrier is an interposer.

5. The electronic component of claim 4, wherein the interposer comprises at least one redistribution layer.

6. The electronic component of claim 1, wherein the first device die is hybrid bonded to the carrier.

7. The electronic component of claim 1, wherein the encapsulant comprises particles embedded therein, and wherein an interface between a top surface of the encapsulant and a bottom surface of the cover element lacks ground particles.

8. The electronic component of claim 1, wherein a top surface of the encapsulant adjacent the bottom surface of the cover element is an unpolished surface.

9. An electronic component comprising:
a first device die bonded to a carrier;
an encapsulant encapsulating side surfaces of the first device die; and
a cover element directly bonded to a top surface of the first device die,
wherein the encapsulant comprises particles embedded therein, and wherein an interface between a top surface of the encapsulant and a bottom surface of the cover element lacks ground particles.

10. The electronic component of claim 9, wherein the first device die is hybrid bonded to the carrier.

11. The electronic component of claim 9, wherein the interface between a top surface of the encapsulant and a bottom surface of the cover element lacks ground particles.

12. The electronic component of claim 9, wherein the particles comprise stress relief particles.

13. The electronic component of claim 9, wherein the particles comprise thermally conducting particles.

14. The electronic component of claim 9, wherein the particles comprise carbides, graphene, or alumina.

15. The electronic component of claim 9, wherein the cover element comprises a heat dissipation wafer.

16. The electronic component of claim 9, wherein the carrier is an interposer.

17. The electronic component of claim 16, wherein the interposer comprises at least one redistribution layer.

18. The electronic component of claim 9, further comprising a second device die stacked in a second device level above the first device die, the second device die directly bonded to the first device die.

19. The electronic component of claim 9, wherein the first die comprises a memory die or a processor die.

20. (canceled)

21. (canceled)

22. The electronic component of claim 9, further comprising a second device die hybrid bonded to the carrier adjacent to the first device die in the first device level.

23. (canceled)

24. The electronic component of claim 9, further comprising a conformal protective layer located over the carrier, the sides of the first die and the top surface first device die.

25. (canceled)

26. (canceled)

27. (canceled)

28. The electronic component of claim 9, further comprising at least one heat dissipation element attached to the carrier.

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. An electronic component comprising:
a first device die directly bonded to a carrier;
an encapsulant encapsulating side surfaces of the first device die; and
a cover element directly bonded to a top surface of the first device die,
wherein a top surface of the encapsulant adjacent a bottom surface of the cover element is an unpolished surface.

44. The electronic component of claim 43, wherein an interface between the top surface of the encapsulant and the bottom surface of the cover element comprises an adhesive bond between the organic encapsulant and the cover element.
